(19) United States
(12) Patent Application Publication
(10) Pub. No.: US 2008/0191356 A1
(43) Pub. Date: Aug. 14, 2008

(54) Power Semiconductor

(75) Inventors: Herbert Leibold, Wilhermsdorf (DE); Hubert Schierling, Erlangen (DE)

Correspondence Address: HENRY M FEIEREISEN, LLC;HENRY M FEIEREISEN, 708 THIRD AVENUE, SUITE 1501, NEW YORK, NY, 10017, US

(73) Assignee: Siemens Aktiengesellschaft, Munchen (DE)

(21) Appl. No.: 11/568,053

(22) PCT Filed: Apr. 18, 2005
(86) PCT No.: PCT/EP05/51688

§ 371 Date: Oct. 18, 2006

(30) Foreign Application Priority Data
Apr. 19, 2004 (DE) 10 2004 019 441.6
May 11, 2004 (DE) 10 2004 023 305.5

(51) Int. Cl. H01L 23/485

(52) U.S. Cl. 257/762; 257/E23.021

(57) ABSTRACT

The invention relates to a power semiconductor comprising a substrate (2) whose surfaces are provided with at least one electrically conducting layer (4, 6), at least one semiconductor chip (8) that is connected to an electrically conducting layer (6) of the substrate (2) in an electrically and thermally conducting manner by means of a soldered joint, a film (12) which is made of an electrically isolating material and is in close contact with the surfaces of electrically conducting layer (6) and the semiconductor chip (8), and a planar contact that is applied to the film (12). According to the invention, a soft solder whose melting temperature is lower than a maximum operating temperature of the semiconductor chip (8) is used for the soldered joint such that a semiconductor is obtained that is provided with a semiconductor (8) contact which is resistant to temperature variations, making said power semiconductor substantially more robust in case of load alternations.

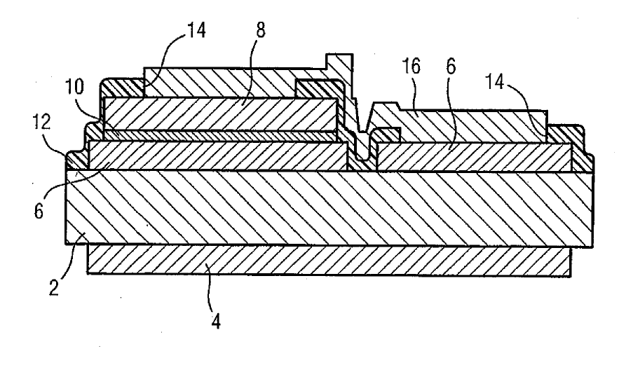

### BACKGROUND OF THE INVENTION

The invention relates to a power semiconductor.

The most widely used mounting technology for power semiconductors is soldering the semiconductor chip to a copper-coated substrate. This substrate may be any organic-based or inorganic-based substrate. For example, the substrate may be a ceramic, a printed circuit board or a printed circuit board having a metal core. The solder contact forms both the mechanical connection and an electrical contact. Thus this soldered joint connects the semiconductor chip electrically and thermally to the electrically conducting layer on the substrate.

The disadvantage with the soldered joint is that the solder suffers fatigue with frequent temperature changes, which degrades the thermal and electrical contact with the conducting layer of the substrate until the semiconductor chip ultimately fails.

Another method for mounting a chip on a substrate is low-temperature bonding. High pressures are required for this method. In addition, adhesive bonding can be used for mounting a chip. This bonding technology is less common for power semiconductors, however, because of poorer thermal properties.

This soldered joint electrically connects one contact of the semiconductor chip to a conducting layer of the substrate. The other contacts of the semiconductor chip are located on the remote side of the substrate from the conducting layer. These contacts are connected to other conducting layers of the substrate by heavy-wire bonding.

Laid-open Specification WO 03/030247 A2 discloses a power semiconductor according to the preamble of claim 1. In this power semiconductor, the heavy-wire bonding wires are replaced by planar conductors. This method of contact-making has a number of advantages compared with the wire bond connection, for example it is far more robust when the power semiconductor is subject to frequent changes in load. The semiconductor chip and its bonding wires heat up and cool down with these changes in load, producing significant mechanical stresses that may lead to premature failure of the contact. This stress also applies to the soldered joint of the semiconductor chip, with the temperature variations causing solder fatigue.

The publication entitled “Flüssige Lötverbindungen—eine alternative Verbindungstechnik für die Elektronik” (“Liquid solder joints—an alternative bonding technology for electronic circuits”), printed in the German journal “VTE—Aufbau und Verbindungstechnik in der Elektronik”, Volume 13 (2001), Book 3, pages 129 to 133, presents liquid soldered joints. One version of the liquid soldered joint is called Permanent Liquid Solder Design (PLSD). This soldered joint is in the liquid state over the full range of the intended operating temperatures of a bonded semiconductor chip. Another version, in which the soldered joint is only in the liquid state in a certain range of the intended operating temperatures, is called Temporary Liquid Solder Design (TLSD). These liquid soldered joints only perform the job of electrical and thermal conduction. Hence the mechanical stability must additionally be provided by a “support material”, which also fixes the molten solder material in its correct working position. Various temperature-resistant polymers can be chosen as the support material. This support material requires sufficient space around the semiconductor chip to be bonded. In addition, it must be ensured that the liquid solder cannot flow out during operation, i.e. a seal is also required in addition to the support material. This makes such a liquid soldered joint complex to manufacture and correspondingly demanding of space.

### SUMMARY OF THE INVENTION

The object of the invention is to define a power semiconductor having a bond that is resistant to temperature variations.

This object is achieved according to the invention by a power semiconductor which includes a substrate whose surfaces are provided with at least one electrically conducting layer, at least one semiconductor chip that is connected electrically and thermally to an electrically conducting layer of the substrate by means of a soldered joint, a film, which is made of an electrically insulating material and is in close contact with the surfaces of the electrically conducting layer and of the semiconductor chip, and a planar contact that is applied to the film, wherein a soft solder whose melting point is lower than a maximum operating temperature of the semiconductor chip is provided for the soldered joint.

By using, according to the invention, in a power semiconductor, instead of a conventional solder a solder whose melting point is lower than a maximum operating temperature of the semiconductor chip, one obtains a bond that is substantially more robust for both temperature variations and changes in load than conventional soldered joints. Since the semiconductor chip heats up automatically during operation, the solder liquefies depending on the operating temperature of the semiconductor chip, so that even a bond that was hitherto impaired is restored by the liquefying of the solder. Since the film made of electrically insulating material is in close contact with the surfaces of the conducting layer and of the semiconductor chip to be bonded, no additional support material nor any additional seal is required.

### BRIEF DESCRIPTION OF THE DRAWING

The invention is described in more detail below with reference to an example and the enclosed drawing, where the FIGURE shows schematically a cross-section through a power semiconductor according to the invention.

### DETAILED DESCRIPTION OF PREFERRED EMBODIMENTS

In the FIGURE, 2 denotes a substrate, 4 denotes a lower electrically conducting layer, 6 an upper electrically conducting layer and 8 a semiconductor chip. These electrically conducting layers 4 and 6 are made of copper. The semiconductor chip 8 is a power semiconductor chip, in particular an Insulated Gate Bipolar Transistor chip (IGBT chip). A layer 10 made of solder is arranged between the semiconductor chip 8 and the upper electrically conducting layer 6 of the power semiconductor. A film 12 made of an electrically insulating material lies in close contact with the surfaces of the substrate 2, of the upper electrically conducting layer 6 and of the semiconductor chip 8. To enable contact to be made with the upper contacts, for example emitter and gate contact, of the semiconductor chip 8, this film 12, for example a polyimide-based or epoxy-based film, has a window 14, which exposes these contact surfaces of the semiconductor chip 8. A layer 16 made of electrically conducting material is applied over the whole surface of this film 12 including its window 14. A soft solder whose melting point is lower than a maximum operating temperature of the semiconductor chip 8 is provided as solder for the soldered joint 10. Specifying the value of the melting point of the soft solder as soldered joint 10 defines the operating range of the semiconductor chip 8 in which the soldered joint 10 is liquid. The film 12 made of electrically insulating material, lying in close contact with all sides of the semiconductor chip 8, fixes the semiconductor chip 8 mechanically in its position and encloses the solder volume. No additional holders are thus required for fixing the semiconductor chip 8 while the soft solder is liquefied. When this film 12 is laminated on under vacuum, the arrangement is heated under pressure. A die is used for this, which also fixes the semiconductor chip 8 in its intended position. The liquefying of the solder thus means there are no constraints placed on the laminating process.

If the power semiconductor is always operated only in the partial-load range below a specified melting point of the solder, there is still the risk of the soldered joint degrading with associated deterioration in the thermal contact resistance. In such a situation, the semiconductor chip 8 gets hotter automatically, thereby liquefying the solder. This impaired soldered joint is restored to its original form by the solder liquefying.

One hence obtains a power semiconductor having a bond of the semiconductor chip 8 that is resistant to temperature variations, so that said power semiconductor is substantially more robust to changes in load.

1. A power semiconductor, comprising:
a substrate having a surface;
an electrically conducting layer disposed on the surface;
at least one semiconductor chip disposed on and electrically and thermally connected to the electrically conducting layer by a solder joint;
a film made of an electrically insulating material and contacting a surface of the electrically conducting layer and of the semiconductor chip; and
a planar contact applied to the film,
wherein the solder joint comprises a soft solder with a melting temperature that is lower than a maximum operating temperature of the semiconductor chip.

2. The power semiconductor of claim 1, wherein the substrate is made of an organic material.

3. The power semiconductor of claim 1, wherein the substrate is made of an inorganic material.

4. The power semiconductor of claim 1, wherein the electrically conducting layer is made of copper.

5. The power semiconductor of claim 1, wherein the film is laminated on surfaces of the electrically conducting layer and of the semiconductor chip.

6. The power semiconductor of claim 1, wherein the film is made of a thermoplastic material.

7. The power semiconductor of claim 1, wherein the film is made of a thermosetting plastic material.

8. The power semiconductor of claim 1, wherein the substrate has a surface facing away from the semiconductor chip, and further comprising a further electrically conducting layer disposed on the surface facing away from the semiconductor chip.
